(19) United States
(12) Patent Application Publication
(10) Pub. No.: US 2017/0113926 A1
(43) Pub. Date: Apr. 27, 2017

(54) MEMS CHIP SCALE PACKAGE

(71) Applicant: Robert Bosch GmbH, Stuttgart (DE)

(72) Inventors: Eric Ochs, Pittsburgh, PA (US); Jay S. Salmon, Wilkinsburg, PA (US); Ricardo Ehrenpfordt, Kortnal-Munchingen (DE)

(21) Appl. No.: 15/340,126

(22) Filed: Nov. 1, 2016

Related U.S. Application Data
(62) Division of application No. 13/316,119, filed on Dec. 9, 2011, now abandoned.

(51) Int. Cl. B81C 1/00; H04R 19/04; H04R 19/00; B81B 7/00

(52) U.S. Cl. CPC B81C 1/0023; B81B 7/007; H04R 19/04; H04R 19/005; B81B 2201/0257; B81B 2207/07; B81C 2203/0136; B81C 2203/0792; H04R 2201/003

(57) ABSTRACT

A flip-chip manufactured MEMS device. The device includes a substrate and a MEMS die. The substrate has a plurality of bumps, a plurality of connection points configured to electrically connect the MEMS device to another device, and a plurality of vias electrically connecting the bumps to the connections points. The MEMS die is attached to the substrate using flip-chip manufacturing techniques, but the MEMS die is not subjected to processing normally associated with creating bumps for flip-chip manufacturing.

### RELATED APPLICATIONS

This patent application is a divisional application of co-pending U.S. patent application Ser. No. 13/316,119, filed Dec. 9, 2011, the content of which is hereby incorporated by reference.

### BACKGROUND

The invention relates to the manufacture of MEMS devices. Specifically, the invention relates to the flip chip bonding of MEMS devices on to substrates, circuit boards or carriers using flip chip interconnect methods that provide both electrical interconnects and an air tight seal between the MEMS device and the carrier. Additionally, the invention addresses compatibility issues associated with plating processes typically associated with wafer bumping and MEMS devices by moving processes that are incompatible with the MEMS die to the substrate.

Wire bonding is a technology in which electronic components or chips are positioned face up and connected to a circuit board or substrate with a wire connection. Flip chip microelectronic assembly is the direct electrical connection of face-down (hence, “flipped”) electronic components onto substrates, circuit boards, or carriers, by means of conductive interconnects between the chip bond pads and the substrates, circuit board, or carrier.

### SUMMARY

The package size of current MEMS devices is limited by space requirements for wire bonding between the die and the substrate and the surface area required to form a suitable seal between the MEMS chip and the substrate. Moving to flip chip assembly allows for package size reduction, batch processing of die to substrate interconnects, and enhanced form factor of the MEMS to substrate seal. The use of printed or wet chemistry bumping technology in manufacturing MEMS devices poses a significant process development challenge due to the sensitive free moving mechanical structures included in MEMS devices.

In one embodiment, the invention provides a flip-chip manufactured MEMS device. The device includes a substrate and a MEMS die. The substrate has a plurality of raised structures, a plurality of connection points configured to electrically connect the MEMS device to another device, and a plurality of vias electrically connecting the raised structures to the connections points. The MEMS die is attached to the substrate using flip-chip manufacturing techniques, but the MEMS die is not subjected to processing normally associated with creating raised structures for flip-chip manufacturing. In other words, the die is attached without placing bumps on the die.

In addition to providing electrical interconnects for flip-chip mounted devices, embodiments of the invention also provide an acoustic sealing between the actual MEMS die and the substrate.

Other aspects of the invention will become apparent by consideration of the detailed description and accompanying drawings.

### BRIEF DESCRIPTION OF THE DRAWINGS

FIG. 1a is a top view of a top-port MEMS microphone.

FIG. 1b is a side view of the top-port MEMS microphone.

FIG. 1c is a bottom view of the top-port MEMS microphone.

FIG. 1d is a perspective view of the top-port microphone.

FIG. 1e is a cross-sectional view of the top-port microphone along line 1e-1e.

FIG. 2a is a top view of a silicon cap of the top-port microphone.

FIG. 2b is a side view of the silicon cap of the top-port microphone.

FIG. 2c is perspective view of the silicon cap of the top-port microphone.

FIG. 2d is cross-sectional view of the silicon cap of the top-port microphone along line 2d-2d.

FIG. 3a is a top view of a bottom-port MEMS microphone.

FIG. 3b is a side view of the bottom-port MEMS microphone.

FIG. 3c is a bottom view of the bottom-port MEMS microphone.

FIG. 3d is a perspective view of the bottom-port MEMS microphone.

FIG. 3e is a cross-sectional view of the bottom-port MEMS microphone along line 3e-3e.

FIG. 4a is a top view of the silicon cap of the bottom-port MEMS microphone.

FIG. 4b is a side view of the silicon cap of the bottom-port MEMS microphone.

FIG. 4c is a bottom view of the silicon cap of the bottom-port MEMS microphone.

FIG. 4d is a first cross-sectional view of the silicon cap along line 4d-4d.

FIG. 4e is second cross-sectional view of the silicon cap along line 4e-4e.

FIG. 5a is top view of a substrate carrier for bottom-port MEMS microphones.

FIG. 5b is side view of the substrate carrier for bottom-port MEMS microphones.

FIG. 6a is a top view of a plurality of bottom-port MEMS microphones on a single substrate carrier.

FIG. 6b is a side view of a plurality of bottom-port MEMS microphones on a single substrate carrier.

FIG. 6c is perspective view of a plurality of bottom-port MEMS microphones on a single substrate carrier.

FIG. 7 is schematic view of an alternative embodiment of a bottom-port MEMS microphone.

### DETAILED DESCRIPTION

Before any embodiments of the invention are explained in detail, it is to be understood that the invention is not limited in its application to the details of construction and the arrangement of components set forth in the following description or illustrated in the following drawings. The invention is capable of other embodiments and of being practiced or of being carried out in various ways.

Flip-chip manufacturing techniques allow higher density electrical connections than can be achieved with wire bonding techniques generally used in MEMS device manufacturing. However, the processing involved with flip-chip manufacturing can damage MEMS dies. The invention addresses these issues and enables the use of flip-chip manufacturing for MEMS devices. The descriptions below are given for MEMS microphones; however, the invention has application for other devices (MEMS or not).

Some of the embodiments described below use a copper (Cu) pillar technology. U.S. Pat. No. 6,681,982, filed Jun. 12, 2002, the entire content of which is hereby incorporated by reference, describes such Cu pillar technology.

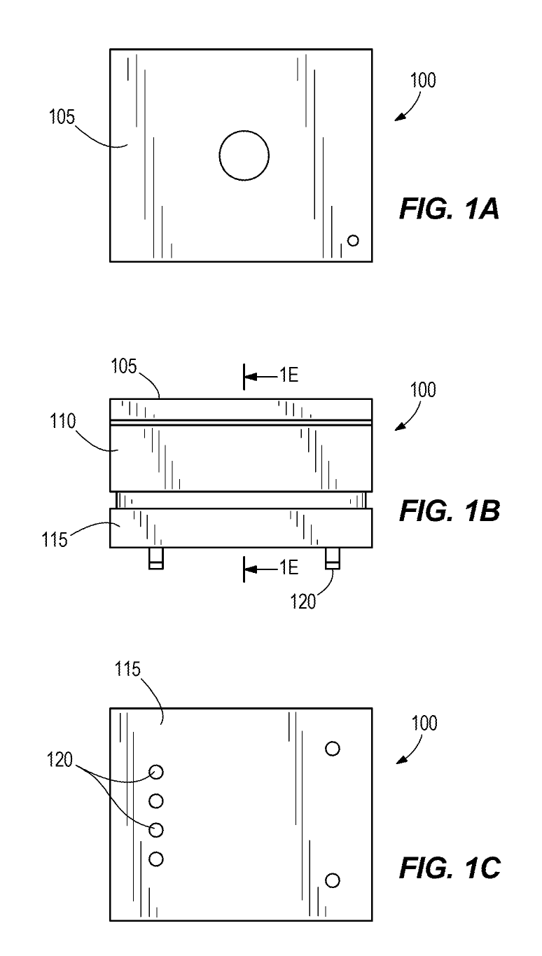

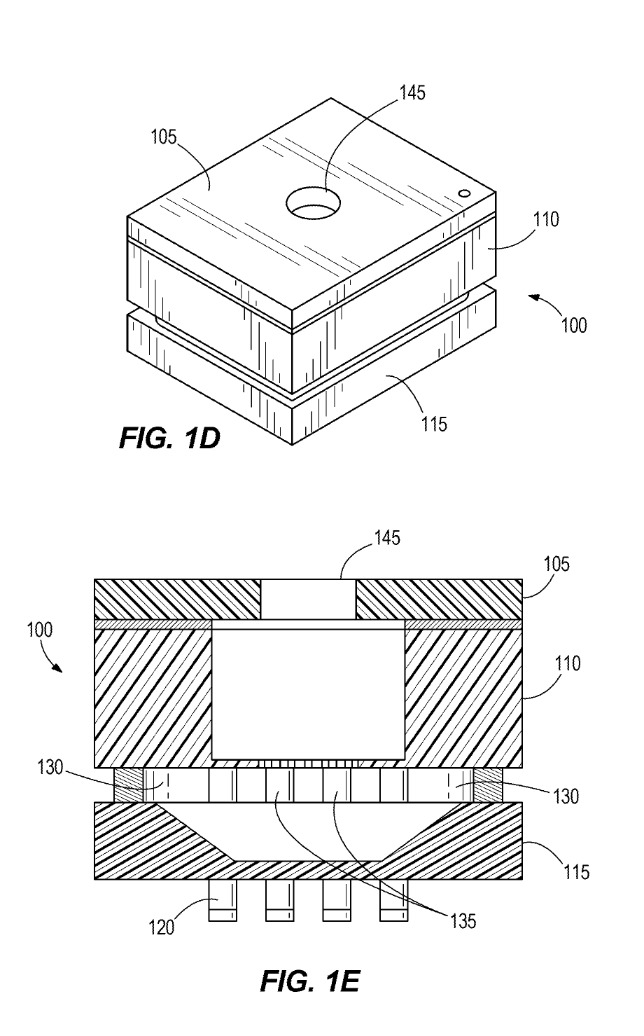

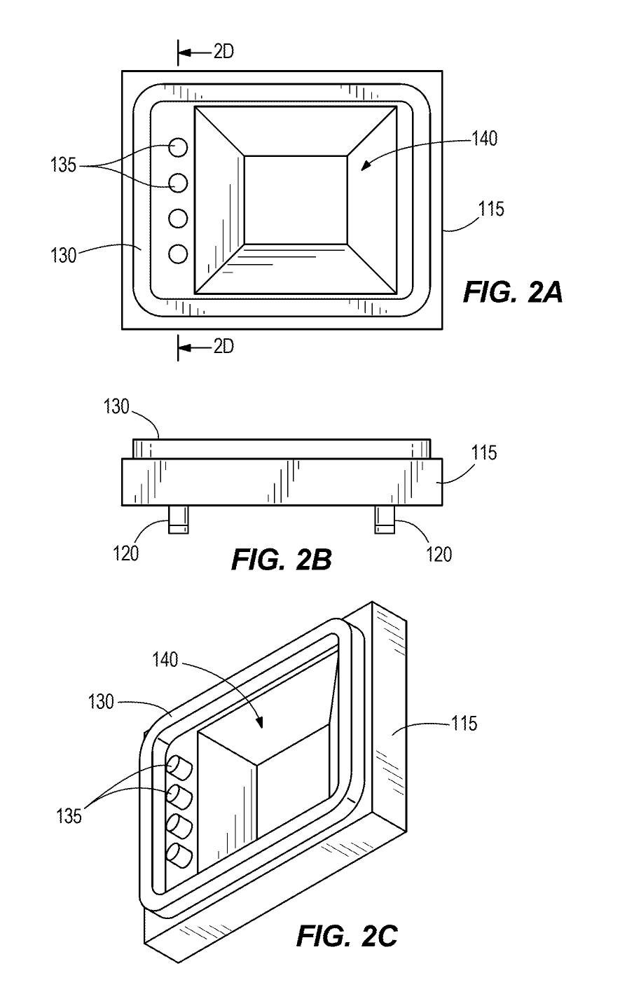

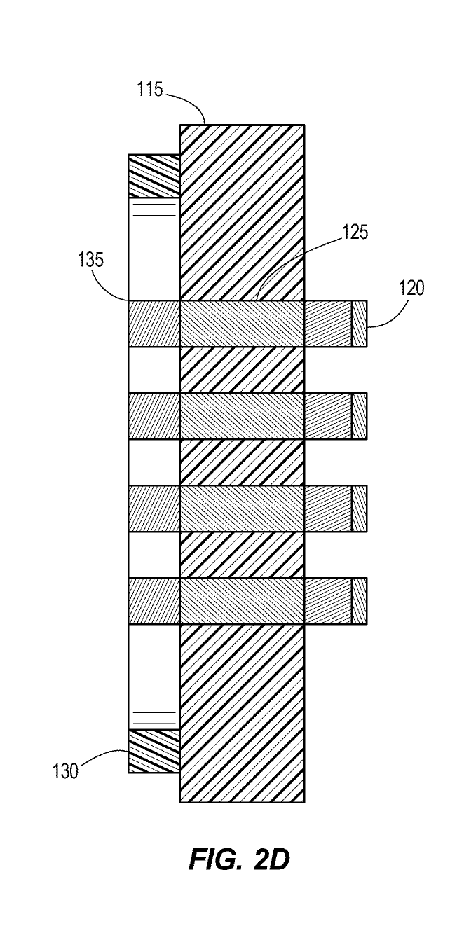

FIGS. 1a, 1b, 1c, 1d, and 1e show a top-port MEMS microphone 100 incorporating an embodiment of the invention. The microphone 100 includes a lid 105, a CMOS MEMS die 110, and a silicon cap 115. FIGS. 2a, 2b, and 2c show the silicon cap 115 in more detail. The silicon cap 115 includes a plurality of first raised structures 120 (i.e., connection points), a plurality of through-silicon-vias (TSVs) 125, a raised ring 130, and a plurality of second raised structures 135. The plurality of first raised structures 120 are for electrically connecting the finished microphone 100 to a device (e.g., a cell phone). The plurality of second raised structures 135 electrically connect to the MEMS die 110. The TSVs 125 electrically connect each of the first raised structures 120 to a respective one of the plurality of second raised structures 135. The MEMS die 110 is attached to the silicon cap 115 using flip-chip methods. The raised ring 130 forms a seal with the MEMS die 110, and along with a cavity 140 formed in the silicon cap 115, creates a back volume for the microphone 100. In the embodiments shown, the raised structures 120 and 135, and the raised ring 130 are formed as copper pillars.

In some embodiments, the top-port MEMS microphone 100 uses an organic substrate with a cavity in place of the silicon cap 115. In such embodiments, the interconnects can be standard printed circuit board (PCB) vias instead of the TSVs used with the silicon cap 115. In addition, the raised structures can be formed using stud bumping and anisotropic conductive epoxy (ACE) or copper pillars.

The use of flip-chip mounting of the MEMS die 110 to the silicon cap 115, and the attaching of the pillars/bumps to the silicon cap 115 protects the moveable mechanical structures of the MEMS die 110 from being damaged by the manufacturing process. The lid 105 includes an acoustic port 145, and is attached to the MEMS die 110 before or after flip-chip mounting of the die 110 to the cap 115.

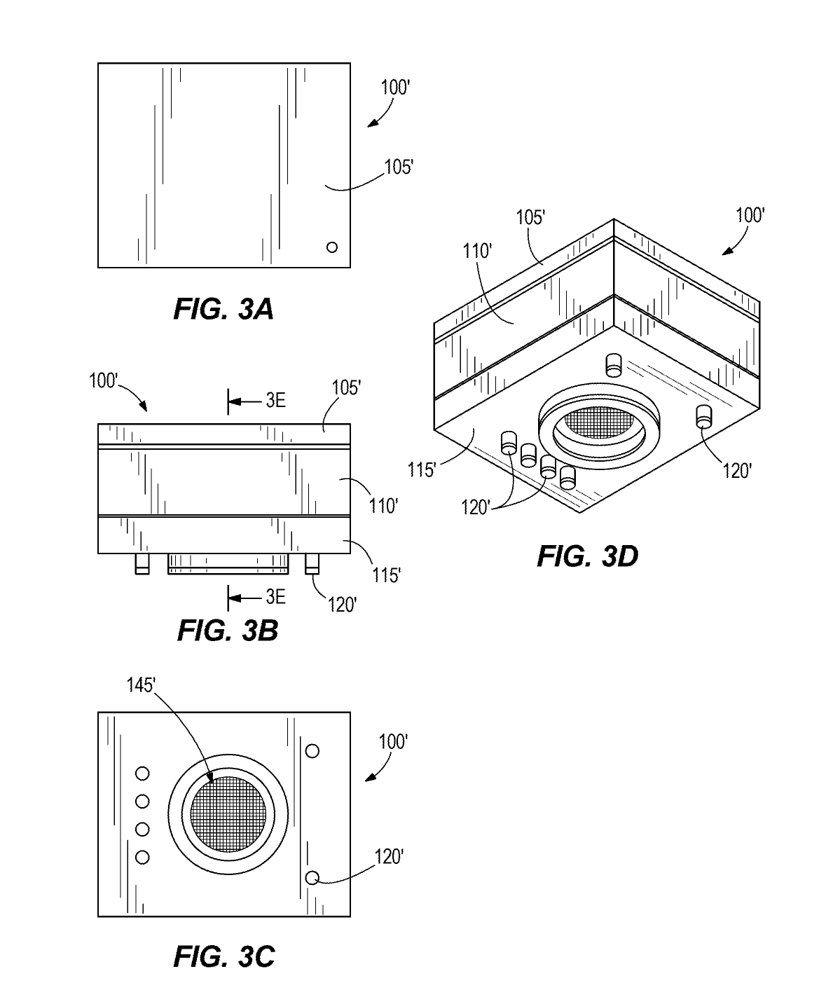

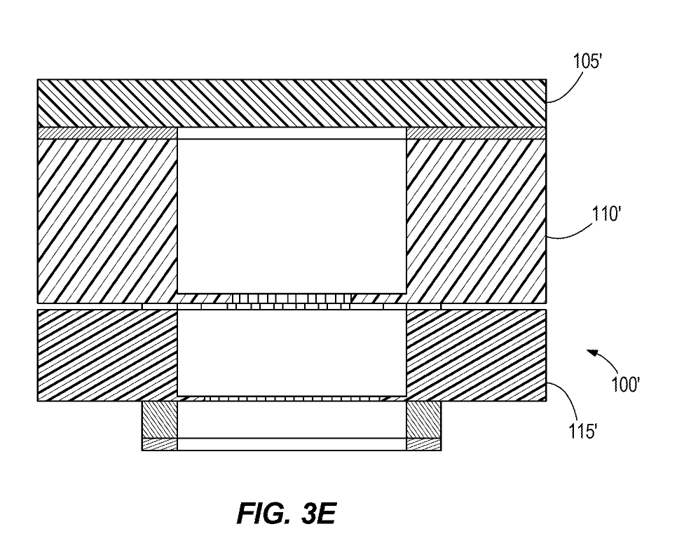

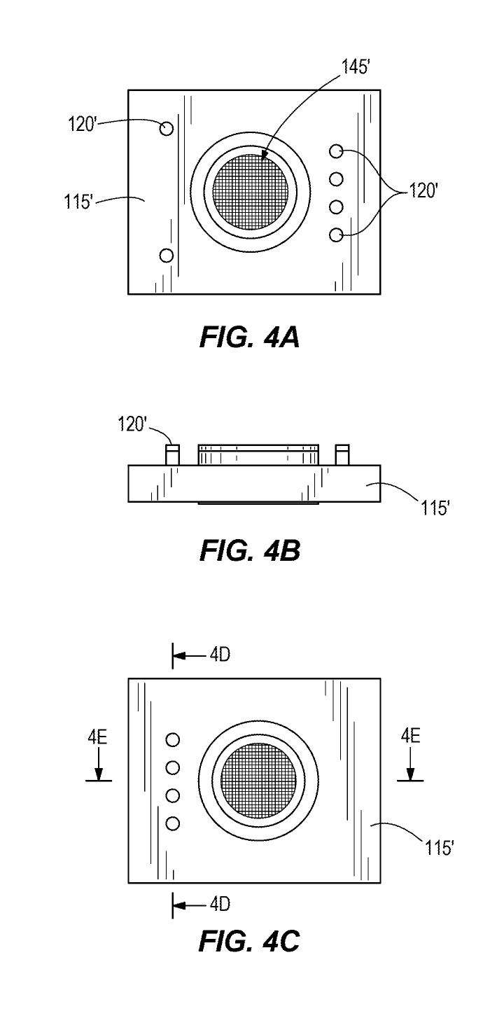

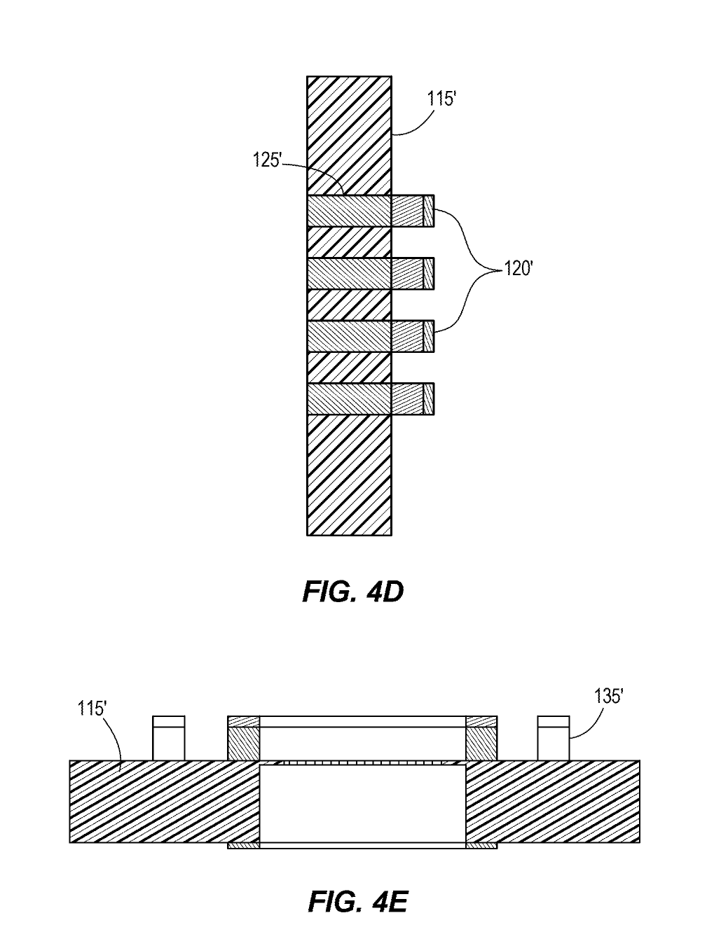

FIGS. 3a, 3b, 3c, 3d, and 3e show a bottom-port MEMS microphone 100′ incorporating an embodiment of the invention. The microphone 100′ includes a lid 105′, a CMOS MEMS die 110′, and a silicon cap 115′. FIGS. 4a, 4d, and 4e show the silicon cap 115′ in more detail. The silicon cap 110′ includes a plurality of first raised structures 120′, a plurality of TSVs 125′, a raised ring 130′, and a plurality of second raised structures 135′. The plurality of first raised structures 120′ are for electrically connecting the finished microphone 100′ to a device (e.g., a cell phone). The plurality of second raised structures 135′ electrically connect to the MEMS die 110′. The TSVs 125′ electrically connect each of the first raised structures 120′ to a respective one of the plurality of second raised structures 135′. The MEMS die 110′ is attached to the silicon cap 115′ using flip-chip methods. The raised ring 130′ forms a seal with the MEMS die 110′. In the embodiments shown, the raised structures 120′ and 135′, and the raised ring 130′ are formed as copper pillars.

The addition of a particle screen embedded or machined into the carrier can act as a barrier to particles entering the device cavity. This screen can also serve as an EMI/ESD shield for sensitive structures inside the packaged device.

In some embodiments, the bottom-port MEMS microphone 100′ uses an organic substrate in place of the silicon cap 115′. In such embodiments, the interconnects can be standard PCB vias instead of the TSVs used with the silicon cap 115′. In addition, the raised structures can be formed using stud bumping and anisotropic conductive epoxy (ACE) or copper pillars. The lid 105′ can be connected using any of several interconnect technologies including epoxy, soft solder, etc.

The microphone 100′ is similar to the microphone 100 of FIGS. 1 and 2 except that the silicon cap 115′ includes an acoustic port 145′ (which can be either formed as a hole or a mesh structure by etching or machining technologies), and the lid 105′ does not include an acoustic port. In addition, the lid 105′ combines with the MEMS die 110′ to form the back volume.

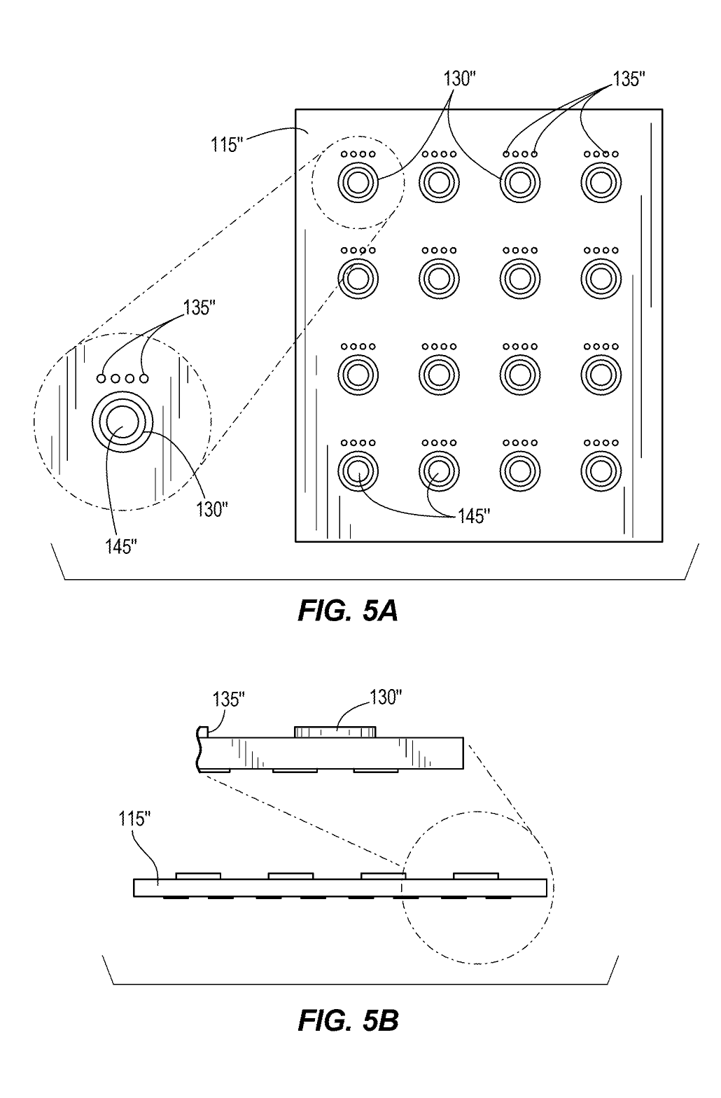

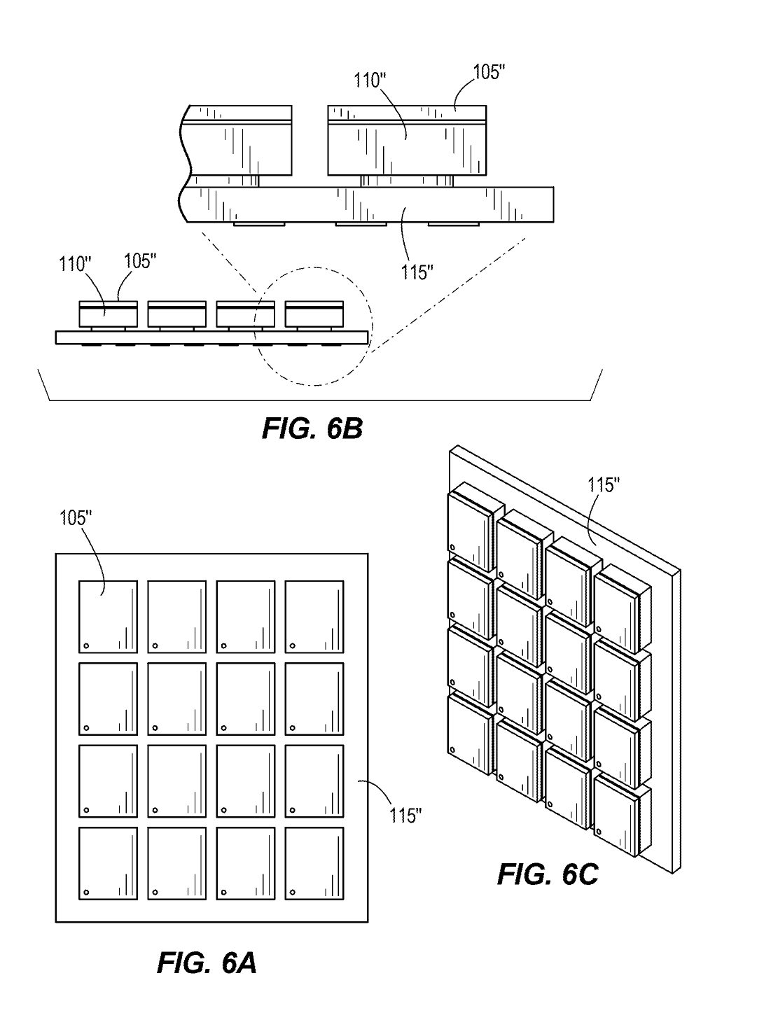

FIGS. 5a and 5b show a substrate carrier 115″ for a bottom port MEMS microphone. The carrier 115″ has been populated with a plurality of raised rings 130″ and a plurality of raised structure interconnects 135″. The carrier 115″ has also been modified to include a plurality of acoustic ports 145″. FIGS. 6a, 6b, and 6c show a plurality of MEMS dies 110″ and lids 105″ that have been flip-chip mounted to the substrate carrier 115″. Following mounting of the MEMS dies 110″, the substrate carrier 115″ is cut to create a plurality of bottom-port MEMS microphones 100′ (see FIGS. 3 and 4).

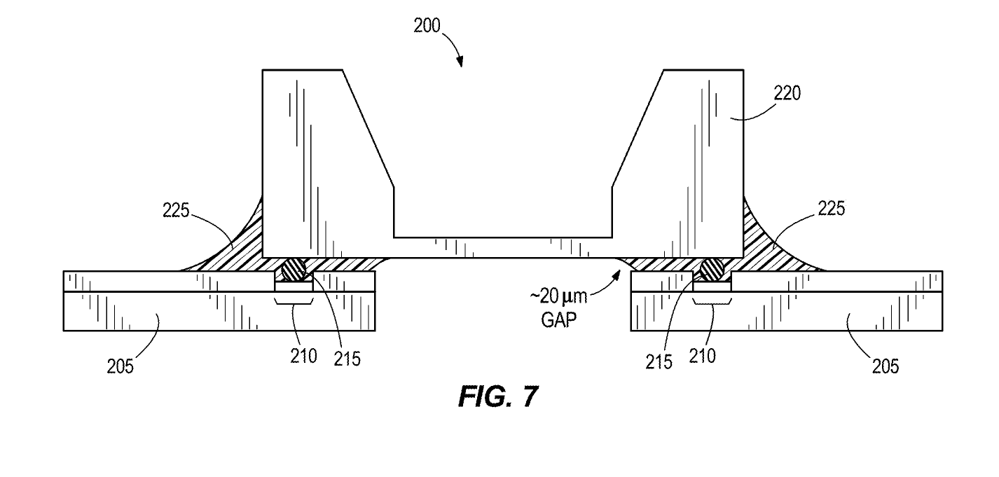

FIG. 7 shows another embodiment of a flip-chip assembled MEMS microphone 200. A substrate 205 includes pads on the top side 210 which hold stud bumps 215. The stud bumps can be either applied to the substrate 205, or the MEMS die 220. The MEMS die 220 is positioned on the substrate 205 via flip-chip methods. An underfill 225 is then added to seal the back volume and stabilize the components of the microphone 200. I

In another embodiment an anisotropic conductive epoxy (ACE) 225 is applied to either the substrate or the MEMS die after the stud bumping, but prior to the flip chip mounting of the MEMS die to the substrate. The ACE seals the back volume and mechanically stabilizes the components of the microphone 200.

The above embodiments are meant to be exemplary, and not limiting. For example, the vias 125 can electrically connect more than one first raised structure 120 to one or more second raised structures 135 and/or vice versa.

Various features and advantages of the invention are set forth in the following claims.

What is claimed is:

1. A method of manufacturing a MEMS device, the method comprising:
creating a substrate with a plurality of vias;
forming a plurality of raised structures on the substrate, the raised structures connected to the vias;
forming a plurality of connection points on the substrate, the connection points connected to the vias; and
mounting a MEMS die on the plurality of raised structures using flip-chip techniques.

2. The method of claim 1, further comprising forming an acoustic seal by at least one of the plurality of raised structures, wherein the raised structure is a ring.

3. The method of claim 1, further comprising attaching the MEMS die to the substrate using flip-chip manufacturing techniques.

4. The method of claim 1, further comprising providing a relatively high density of electrical connections by the plurality of raised structures as compared to wire bonding.

5. The method of claim 1, further comprising forming the plurality of raised structures on the substrate using wet processing.

6. The method of claim 1, further comprising mounting the MEMS die to the substrate by an underfill, wherein the plurality of raised structures are solder balls lying in grooves on the substrate.
